(19) United States
(12) Patent Application Publication
(10) Pub. No.: US 2017/0338113 A1
(43) Pub. Date: Nov. 23, 2017

(54) Fabrication Method of Oxide Semiconductor Thin Film and Fabrication Method of Thin Film Transistor

(71) Applicant: BOE TECHNOLOGY GROUP CO., LTD., Beijing (CN)

(72) Inventor: Xiangyong KONG, Beijing (CN)

(21) Appl. No.: 15/524,525

(22) PCT Filed: Jan. 21, 2016
(86) PCT No.: PCT/CN2016/071546

§ 371 Date: May 4, 2017

(30) Foreign Application Priority Data
Aug. 21, 2015 (CN) 201510520915.X

(51) Int. Cl. H01L 21/02; H01L 29/66; H01L 29/786

(52) U.S. Cl. CPC H01L 21/02472; H01L 29/7869; H01L 29/66969; H01L 21/02667; H01L 21/02488; H01L 21/02609; H01L 21/02565; H01L 21/02502; H01L 21/02658

(57) ABSTRACT

The present invention provides a fabrication method of an oxide semiconductor thin film and a fabrication method of a thin film transistor, belongs to the field of display technology, and can solve the problem of high crystallization temperature and high difficulty in fabrication process of an oxide semiconductor thin film in the existing oxide thin film transistor. The fabrication method of an oxide semiconductor thin film of the present invention includes: forming an induction layer thin film on a substrate; and forming an oxide semiconductor thin film on the substrate formed with the induction layer thin film, and performing an annealing process on the oxide semiconductor thin film to crystallize the oxide semiconductor thin film.

### TECHNICAL FIELD

The present invention belongs to the field of display technology, and particularly relates to a fabrication method of an oxide semiconductor thin film and a fabrication method of a thin film transistor.

### BACKGROUND

With the continuous development of display technology, oxide thin film transistors are widely used due to their characteristics such as high electron mobility, low fabrication temperature, good uniformity, transparency to visible light, low threshold voltage, etc.

In the existing method of fabricating an oxide thin film transistor, an oxide active layer of the oxide thin film transistor is generally made of a metal oxide, which has poor stability and is susceptible to oxygen, hydrogen and water in the etching environment. Thus, in order to prevent the oxide active layer from being affected when etching a source electrode and a drain electrode of the oxide thin film transistor, an etch stop layer is additionally provided for protecting the oxide active layer.

Inventors found that at least the following problems exist in the prior art. Since the etch stop layer is added, i.e., a process of forming the etch stop layer is added in the fabrication process of an oxide thin film transistor, the characteristics of the oxide thin film transistor may be affected if the process of forming the etch stop layer is not controlled properly, and for example, the thickness of the formed etch stop layer is thus uneven. Therefore, the addition of the etch stop layer results in not only complicated fabrication process and increased fabrication costs of the oxide thin film transistor but also reduced production capacity and yield of the fabricated substrates.

In order to obviate the problems caused by adding the etch stop layer in the oxide thin film transistor in the prior art, as the oxide active layer of the oxide thin film transistor, a crystalline oxide active layer may be adopted so as to avoid addition of the etch stop layer. However, the crystalline oxide active layer is formed by directly heating the oxide semiconductor thin film to crystallize the oxide semiconductor thin film, crystallization temperature is very high, preparation process is difficult, and other film layers are apt to be affected during crystallization. Thus, how to reduce the crystallization temperature of the oxide active layer has become the technical problem to be urgently solved in the art.

### SUMMARY

The technical problem to be solved by the present invention includes providing a fabrication method of an oxide semiconductor thin film and a fabrication method of a thin film transistor, in which the oxide semiconductor thin film has a low crystallization temperature and optimized properties.

The technical solutions adopted to solve the technical problem of the present invention include a fabrication method of an oxide semiconductor thin film, which includes steps of:

forming an induction layer thin film on a substrate; and

forming an oxide semiconductor thin film on the substrate formed with the induction layer thin film, and performing an annealing process on the oxide semiconductor thin film to crystallize the oxide semiconductor thin film.

Optionally, before the step of forming an oxide semiconductor thin film, the fabrication method further includes:

performing an annealing process on the formed induction layer thin film.

Further optionally, the annealing process is performed on the formed induction layer thin film at an annealing temperature ranging from 300° C. to 600° C.

Optionally, the induction layer thin film has a thickness ranging from 5 nm to 50 nm, and the oxide semiconductor thin film has a thickness ranging from 30 nm to 200 nm.

Optionally, the annealing process is performed on the oxide semiconductor thin film at an annealing temperature ranging from 300° C. to 600° C.

Optionally, before the step of forming an induction layer thin film, the fabrication method further includes:

forming a buffer layer on the substrate,

wherein the induction layer thin film is formed on the buffer layer.

Further optionally, the buffer layer includes at least one layer formed by silicon oxide or silicon nitride.

Further optionally, the buffer layer has a thickness ranging from 150 nm to 300 nm.

Optionally, the induction layer thin film is made of zinc oxide.

Optionally, the oxide semiconductor thin film is made of any one of indium gallium zinc oxide, indium zinc oxide, indium tin oxide and indium gallium tin oxide.

Optionally, crystallizing the oxide semiconductor thin film specifically includes: converting the oxide semiconductor thin film into a polycrystalline oxide semiconductor thin film or an oxide semiconductor thin film with a c-axis preferential orientation growth.

The technical solutions adopted to solve the technical problem of the present invention include a fabrication method of a thin film transistor, which includes a step of forming an active layer, wherein, the step of forming an active layer includes:

forming an induction layer thin film on a substrate; and

forming an oxide semiconductor thin film on the substrate formed with the induction layer thin film, and performing an annealing process on the oxide semiconductor thin film to crystallize the oxide semiconductor thin film; and

performing a patterning process on the substrate formed with the crystallized oxide semiconductor thin film to form a pattern including the active layer.

Optionally, before the step of forming the induction layer thin film, the fabrication method further includes:

forming a pattern including a gate electrode of the thin film transistor on the substrate through a patterning process; and

forming a gate insulation layer on the substrate formed with the gate electrode,

wherein the induction layer thin film is formed on the gate insulation layer.

Optionally, after the oxide semiconductor thin film is crystallized and at the same time when a pattern of the active layer is formed, the fabrication method further includes:

forming a source-drain metal film on the substrate formed with the crystallized oxide semiconductor thin film, and forming a pattern including a source electrode and a drain electrode through a patterning process.

The present invention has the beneficial effects as follows.

In the fabrication method of an oxide semiconductor thin film of the present invention, the oxide semiconductor thin film is induced by an induction layer thin film first, an annealing process is then performed on the oxide semiconductor thin film to crystallize the oxide semiconductor thin film, and in this way, heating temperature (i.e., crystallization temperature) is much lower, and the difficulty in the fabrication process of the oxide semiconductor thin film is thus reduced, as compared with the case in which the oxide semiconductor thin film is directly heated to be crystallized.

### BRIEF DESCRIPTION OF THE FIGURES

FIG. 1 is a flow chart of a fabrication method of an oxide semiconductor thin film according to a first embodiment of the present invention;

FIG. 2 is a flow chart of a fabrication method of an oxide semiconductor thin film according to a second embodiment of the present invention;

FIG. 3 is a flow chart of a fabrication method of a thin film transistor according to a third embodiment of the present invention; and

FIG. 4 is a schematic diagram of an array substrate according to the third embodiment of the present invention.

### DETAILED DESCRIPTION

To enable those skilled in the art to better understand technical solutions of the present invention, the present invention will be further described in detail below in conjunction with the accompanying drawings and the specific implementations.

### First Embodiment

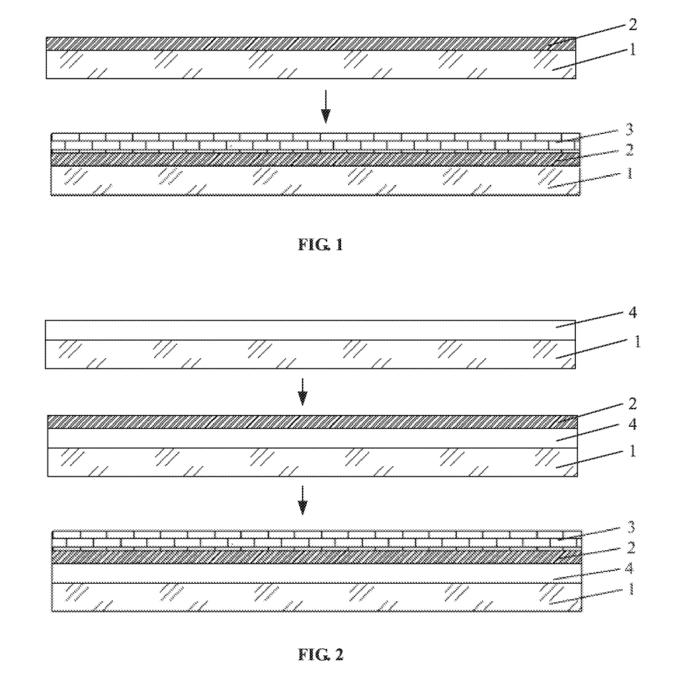

As shown in FIG. 1, the embodiment provides a fabrication method of an oxide semiconductor thin film 3, including the following steps 1 and 2.

Step 1 includes: forming an induction layer thin film 2 on a substrate 1 using a method such as thermal growth, atmospheric chemical vapor deposition, low-pressure chemical vapor deposition, plasma-assisted chemical vapor deposition, sputtering or sol-gel.

Here, the substrate 1 may refer to a substrate on which no film is formed, for example, white glass, or refer to a substrate on which other film(s) or pattern(s) is(are) formed, for example, a substrate on which a buffer layer 4 is formed. The induction layer thin film 2 is preferably made of zinc oxide (ZnO), and preferably has a thickness ranging from 5 nm to 50 nm. It should be noted that, due to the material of the induction layer thin film 2 itself, at least part of the material of the induction layer thin film 2 has been crystallized during deposition, and thus, the induction layer thin film 2 formed in step 1 can be interpreted as an induction layer thin film which is at least partially crystallized.

Step 2 includes: forming an oxide semiconductor thin film 3 on the substrate 1 subjected to step 1 using a method such as thermal growth, atmospheric chemical vapor deposition, low-pressure chemical vapor deposition, plasma-assisted chemical vapor deposition or sputtering, and then performing an annealing process at an annealing temperature ranging from 300° C. to 500° C., so that the oxide semiconductor thin film 3 is induced by the induction layer thin film 2 to be crystallized, specifically, the oxide semiconductor thin film 3 is converted into a polycrystalline oxide semiconductor thin film or an oxide semiconductor thin film with a c-axis preferential orientation growth.

Material of the oxide semiconductor thin film 3 may include at least three elements selected from a group consisting of In (indium), Ga (gallium), Zn (zinc), O (oxygen) and Sn (tin), and the oxide semiconductor thin film 3 is formed on the substrate 1 subjected to step 1 through a process such as sputtering. Further, the oxide semiconductor thin film 3 must contain oxygen and two or more other elements, for example, contain Indium Gallium Zinc Oxide (IGZO), Indium Zinc Oxide (IZO), Indium Tin Oxide (ITO), Indium Gallium Tin Oxide (IGTO), or the like. The oxide semiconductor thin film 3 is preferably made of IGZO or IZO, and preferably has a thickness ranging from 30 nm to 200 nm.

It should be noted that, if the oxide semiconductor thin film 3 is directly heated without being induced by using the induction layer thin film 2 (i.e., the method adopted in the prior art), the temperature required for crystallizing the oxide semiconductor thin film 3 is far higher than the temperature required for heating the oxide semiconductor thin film 3 that has been induced by the induction layer thin film 2 to crystallize the oxide semiconductor thin film 3 in the present embodiment.

Specifically, assuming that the oxide semiconductor thin film 3 is made of IGZO and the IGZO is directly heated to be crystallized, the heating temperature is approximately 800° C.; whereas if an annealing process is performed on the oxide semiconductor thin film 3 that has been induced by the induction layer thin film 2 made of zinc oxide, so as to crystallize the oxide semiconductor thin film 3, the annealing temperature ranges from 300° C. to 500° C., which greatly lowers process difficulty.

In the fabrication method of the oxide semiconductor thin film 3 of the present embodiment, the oxide semiconductor thin film 3 formed on the induction layer thin film 2 is induced by the induction layer thin film 2, so that the oxide semiconductor thin film 3 grows according to crystal orientation of the induction layer thin film 2 to obtain a polycrystalline oxide semiconductor thin film or an oxide semiconductor thin film with a c-axis preferential orientation growth. Crystallization temperature of the oxide semiconductor thin film is relatively low in the present fabrication method, and thus the present fabrication method has relatively low process difficulty and can obtain the oxide semiconductor thin film 3 with optimized properties.

### Second Embodiment

As shown in FIG. 2, the embodiment provides a fabrication method of an oxide semiconductor thin film 3 including steps 1 to 3 as follows.

Step 1 includes: forming a buffer layer 4 on a substrate 1 by a method such as sputtering, thermal evaporation, plasma enhanced chemical vapor deposition, low pressure chemical vapor deposition, atmospheric pressure chemical vapor deposition, electron cyclotron resonance chemical vapor deposition or the like.

The buffer layer 4 includes at least one layer formed by silicon oxide or silicon nitride, and preferably has a thickness ranging from 150 nm to 300 nm. The purpose for forming such a thick buffer layer 4 is to form an effective heat blocking layer for thermal insulation, so that the oxide semiconductor thin film 3 formed in a subsequent step can be fully crystallized.

Step 2 includes: forming an induction layer thin film 2 on the substrate 1 subjected to the above step 1 by a method such as thermal growth, atmospheric chemical vapor deposition, low-pressure chemical vapor deposition, plasma-assisted chemical vapor deposition, sputtering or sol-gel, and performing an annealing process on the formed induction layer thin film 2 at an annealing temperature ranging from 300° C. to 600° C. to fully crystallize the induction layer thin film 2, so that the oxide semiconductor thin film 3 can be better induced and crystallized in the subsequent step.

The induction layer thin film 2 is preferably made of zinc oxide (ZnO), and preferably has a thickness ranging from 5 nm to 50 nm. It should be noted that, due to the material of the induction layer thin film 2 itself, at least part of the material of the induction layer thin film 2 has been crystallized during deposition, then the annealing process is performed on the induction layer thin film 2 to fully crystallize the induction layer thin film 2, and thus, the induction layer thin film 2 formed in step 2 can be interpreted as a crystallized induction layer thin film 2.

Step 3 includes: forming an oxide semiconductor thin film 3 on the substrate 1 subjected to the above step 2 by using a method such as thermal growth, atmospheric chemical vapor deposition, low-pressure chemical vapor deposition, plasma-assisted chemical vapor deposition or sputtering, and then performing an annealing process at an annealing temperature ranging from 300° C. to 500° C., so that the oxide semiconductor thin film 3 is induced by the induction layer thin film 2 to be crystallized, specifically, the oxide semiconductor thin film 3 is converted into a polycrystalline oxide semiconductor thin film or an oxide semiconductor thin film with a c-axis preferential orientation growth.

Material of the oxide semiconductor thin film 3 may include at least three elements selected from a group consisting of In (indium), Ga (gallium), Zn (zinc), O (oxygen) and Sn (tin), and the oxide semiconductor thin film 3 is formed on the substrate 1 subjected to the above step 2 through a process such as sputtering. Further, the oxide semiconductor thin film 3 must contain oxygen and two or more other elements, for example, contain Indium Gallium Zinc Oxide (IGZO), Indium Zinc Oxide (IZO), Indium Tin Oxide (ITO), Indium Gallium Tin Oxide (IGTO), or the like. The oxide semiconductor thin film 3 is preferably made of IGZO or IZO, and preferably has a thickness ranging from 30 nm to 200 nm.

In the fabrication method of the oxide semiconductor thin film 3 of the present embodiment, the oxide semiconductor thin film 3 formed on the induction layer thin film 2 is induced by the induction layer thin film 2, so that the oxide semiconductor thin film 3 grows according to crystal orientation of the induction layer thin film 2 to obtain a polycrystalline oxide semiconductor thin film or an oxide semiconductor thin film with a c-axis preferential orientation growth. Particularly, the buffer layer 4 is formed before the induction layer thin film 2 is deposited (that is, the buffer layer 4 is formed between the substrate 1 and the induction layer thin film 2) to form an effective heat blocking layer, so that the oxide semiconductor thin film 3 formed in the subsequent step can be fully crystallized. Crystallization temperature of the oxide semiconductor thin film is relatively low in the present fabrication method, and thus the present fabrication method has relatively low process difficulty and can obtain the oxide semiconductor thin film 3 with optimized properties.

### Third Embodiment

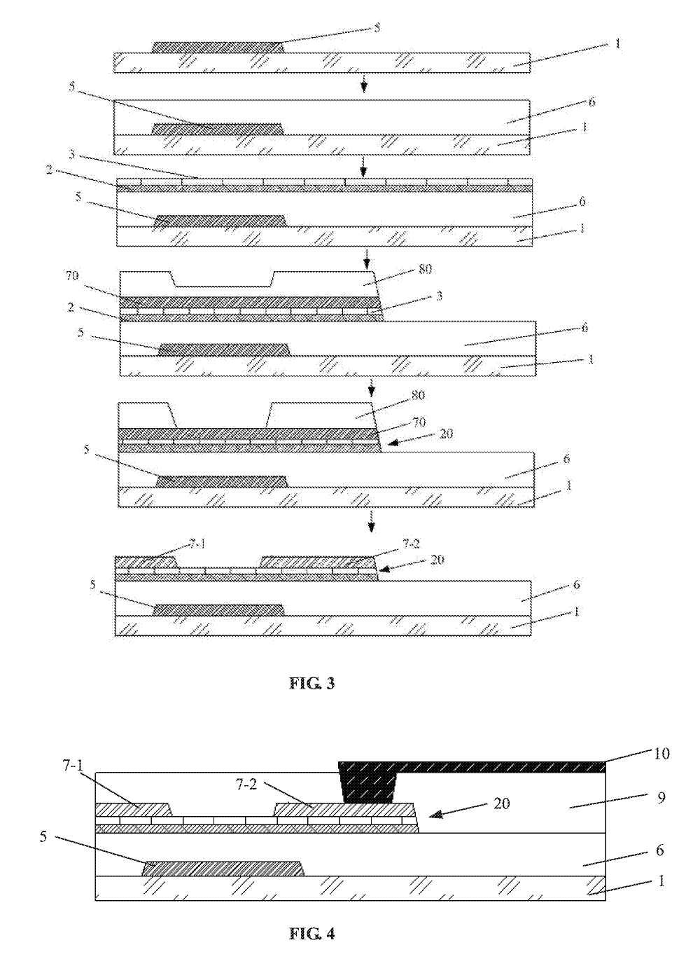

As shown in FIG. 3, the embodiment provides a fabrication method of a thin film transistor, including the steps for forming an oxide semiconductor thin film in the first or second embodiment. Specifically, description is given by taking the case of fabricating a bottom gate type thin film transistor as an example. It should be noted that, in the embodiment of the present invention, a patterning process may include a lithography process only, or include a lithography process and an etching process, and may further include other process for forming a predetermined pattern, such as printing, inkjet, etc.; the lithography process refers to a process of forming a pattern using photoresist, mask, exposure machine and the like, which includes processes such as film formation, exposure, development, and the like. A corresponding patterning process may be selected according to the required structure in the present invention.

The fabrication method of the bottom gate type thin film transistor includes steps 1 to 4 as follows.

Step 1 includes: depositing a layer of gate metal film on a substrate 1 using a magnetron sputtering method, and forming a pattern including a gate electrode 5 of the thin film transistor by a patterning process.

The gate metal film may be a monolayer film formed by one or more of molybdenum (Mo), molybdenum niobium alloy (MoNb), aluminum (Al), aluminum neodymium alloy (AlNd), titanium (Ti) and copper (Cu), or a multilayer composite laminate formed by multiple materials selected from molybdenum (Mo), molybdenum niobium alloy (MoNb), aluminum (Al), aluminum neodymium alloy (AlNd), titanium (Ti) and copper (Cu). Preferably, the gate metal film is a monolayer film formed by Mo, Al, or an alloy containing Mo and Al, or a multilayer composite film formed by multiple materials selected from Mo, Al, or an alloy containing Mo and Al.

Step 2 includes: forming a gate insulation layer 6 on the substrate 1 subjected to step 1 by using a method such as thermal growth, atmospheric chemical vapor deposition, low-pressure chemical vapor deposition, plasma-assisted chemical vapor deposition, sputtering or the like.

The gate insulation layer 6 may be a multilayer composite film formed by one or any two of silicon oxide (SiOx), silicon nitride (SiNx), hafnium oxide (HfOx), silicon oxynitride (SiON), aluminum oxide (AlOx), and the like.

Step 3 includes: sequentially forming an induction layer thin film 2 and an oxide semiconductor thin film 3 on the substrate 1 subjected to step 2, and performing an annealing process on the oxide semiconductor thin film 3 to form a crystallized oxide semiconductor thin film.

Step 3 may be implemented by using the method in the first embodiment, or by using the method in the second embodiment, and thus is not described in detail herein.

Because the gate insulation layer 6 is provided under the oxide semiconductor thin film 3, and can be used for thermal insulation like the buffer layer 4, a step of forming the buffer layer 4 can be omitted in step 3.

Step 4 includes: on the substrate 1 subjected to step 3, first forming a source-drain metal layer 70, then applying a photoresist 80, and performing exposure using a halftone mask or a gray scale mask, so as to form a pattern including an active layer 20, a source electrode 7-1 and a drain electrode 7-2 of the thin film transistor, wherein the active layer 20 is a crystallized active layer, the source electrode 7-1 contacts the active layer 20 through a source contact area, and the drain electrode 7-2 contacts the active layer 20 through a drain contact area.

The source-drain metal layer 70 may be formed by one or more of molybdenum (Mo), molybdenum niobium alloy (MoNb), aluminum (Al), aluminum neodymium alloy (AlNd), titanium (Ti) and copper (Cu), and is preferably formed by Mo, Al or an alloy containing Mo and Al.

At this point, fabrication of the bottom gate type thin film transistor is completed. A passivation layer 9 and a pixel electrode 10 may be sequentially formed on the thin film transistor such that the pixel electrode 10 contacts the drain electrode 7-2, so as to form an array substrate, as shown in FIG. 4.

In the embodiment, the crystallized active layer is formed while being induced by the induction layer thin film, so the oxide semiconductor thin film can be crystallized without high temperature treatment, the crystallized active layer is formed in a subsequent step, and there is no need to form an etch stop layer, thus making the fabrication process easy to implement.

It can be understood that, the above implementations are merely exemplary implementations used for explaining the principle of the present invention, but the present invention is not limited thereto. For those skilled in the art, various modifications and improvements may be made without departing from the spirit and essence of the present invention, and these modifications and improvements are also deemed as falling within the protection scope of the present invention.

1-14. (canceled)

15. A fabrication method of an oxide semiconductor thin film, comprising steps of:
forming an induction layer thin film on a substrate; and
forming an oxide semiconductor thin film on the substrate formed with the induction layer thin film, and performing an annealing process on the oxide semiconductor thin film to crystallize the oxide semiconductor thin film.

16. The fabrication method of an oxide semiconductor thin film according to claim 15, further comprising, before the step of forming an oxide semiconductor thin film, a step of:
performing an annealing process on the formed induction layer thin film.

17. The fabrication method of an oxide semiconductor thin film according to claim 16, wherein, the annealing process is performed on the formed induction layer thin film at an annealing temperature ranging from 300° C. to 600° C.

18. The fabrication method of an oxide semiconductor thin film according to claim 15, wherein, the induction layer thin film has a thickness ranging from 5 nm to 50 nm; and the oxide semiconductor thin film has a thickness ranging from 30 nm to 200 nm.

19. The fabrication method of an oxide semiconductor thin film according to claim 15, wherein, the annealing process is performed on the oxide semiconductor thin film at an annealing temperature ranging from 300° C. to 500° C.

20. The fabrication method of an oxide semiconductor thin film according to claim 15, further comprising, before the step of forming an induction layer thin film, a step of:
forming a buffer layer on the substrate,
wherein the induction layer thin film is formed on the buffer layer.

21. The fabrication method of an oxide semiconductor thin film according to claim 20, wherein, the buffer layer comprises at least one layer formed by silicon oxide or silicon nitride.

22. The fabrication method of an oxide semiconductor thin film according to claim 20, wherein, the buffer layer has a thickness ranging from 150 nm to 300 nm.

23. The fabrication method of an oxide semiconductor thin film according to claim 15, wherein, the induction layer thin film is made of zinc oxide.

24. The fabrication method of an oxide semiconductor thin film according to claim 15, wherein, the oxide semiconductor thin film is made of any one of indium gallium zinc oxide, indium zinc oxide, indium tin oxide and indium gallium tin oxide.

25. The fabrication method of an oxide semiconductor thin film according to claim 15, wherein, crystallizing the oxide semiconductor thin film specifically comprises converting the oxide semiconductor thin film into a polycrystalline oxide semiconductor thin film or an oxide semiconductor thin film with a c-axis preferential orientation growth.

26. The fabrication method of an oxide semiconductor thin film according to claim 16, wherein, crystallizing the oxide semiconductor thin film specifically comprises converting the oxide semiconductor thin film into a polycrystalline oxide semiconductor thin film or an oxide semiconductor thin film with a c-axis preferential orientation growth.

27. The fabrication method of an oxide semiconductor thin film according to claim 17, wherein, crystallizing the oxide semiconductor thin film specifically comprises converting the oxide semiconductor thin film into a polycrystalline oxide semiconductor thin film or an oxide semiconductor thin film with a c-axis preferential orientation growth.

28. The fabrication method of an oxide semiconductor thin film according to claim 18, wherein, crystallizing the oxide semiconductor thin film specifically comprises converting the oxide semiconductor thin film into a polycrystalline oxide semiconductor thin film or an oxide semiconductor thin film with a c-axis preferential orientation growth.

29. The fabrication method of an oxide semiconductor thin film according to claim 19, wherein, crystallizing the oxide semiconductor thin film specifically comprises converting the oxide semiconductor thin film into a polycrystalline oxide semiconductor thin film or an oxide semiconductor thin film with a c-axis preferential orientation growth.

30. A fabrication method of a thin film transistor, comprising a step of forming an active layer, wherein, the step of forming an active layer comprises:
forming an induction layer thin film on a substrate; and
forming an oxide semiconductor thin film on the substrate formed with the induction layer thin film, and performing an annealing process on the oxide semiconductor thin film to crystallize the oxide semiconductor thin film; and
performing a patterning process on the substrate formed with the crystallized oxide semiconductor thin film to form a pattern including the active layer.

31. The fabrication method of a thin film transistor according to claim 30, further comprising, before the step of forming the induction layer thin film, steps of:
forming a pattern including a gate electrode of the thin film transistor on the substrate through a patterning process; and
forming a gate insulation layer on the substrate formed with the gate electrode, wherein the induction layer thin film is formed on the gate insulation layer.

32. The fabrication method of a thin film transistor according to claim 30, further comprising, after the oxide semiconductor thin film is crystallized, and at the same time when a pattern of the active layer is formed, a step of:
forming a source-drain metal film on the substrate formed with the crystallized oxide semiconductor thin film, and forming a pattern including a source electrode and a drain electrode through a patterning process.
